(19) United States
(12) Patent Application Publication
(10) Pub. No.: US 2015/0076665 A1
(43) Pub. Date: Mar. 19, 2015

(54) ALIGNMENT MARK STRUCTURE

(71) Applicant: UNITED MICROELECTRONICS CORP., Hsin-Chu City (TW)

(72) Inventors: Jian-Bin Shiu, Hsinchu County (TW); Min-Ching Chen, Miaoli County (TW)

(73) Assignee: UNITED MICROELECTRONICS CORP., Hsin-Chu City (TW)

(21) Appl. No.: 14/029,815

(22) Filed: Sep. 18, 2013

(51) Int. Cl. H01L 23/544

(52) U.S. Cl. CPC H01L 23/544
USPC 257/620

(57) ABSTRACT

A conductive structure includes a wafer having a scribe line defined thereon, at least a first wiring layer formed in the scribe line, and at least a via layer disposed in the scribe line and under the wiring layer. The first wiring layer includes a main pattern and the via layer includes a closed frame pattern corresponding to the main pattern of the first wiring layer.

### BACKGROUND OF THE INVENTION

1. Field of the Invention

The invention relates to an alignment mark structure, and more particularly, to an alignment mark structure formed by interconnection fabrication process.

2. Description of the Prior Art

In semiconductor device manufacturing processes, semiconductor, dielectric, and conductor layers are formed on a substrate and etched to form patterns for forming gates, fins or openings for accommodating contact plugs or interconnection features. Since the integrated circuits are constructed by layers and layers of semiconductor, dielectric, and conductor features, it is always in need that those features are formed in a substantially planar form.

For example, in the interconnection process, wirings are formed in levels and vias which extend between levels of wirings are reproducibly formed for providing electrical connection. The multi-leveled interconnection structure must be formed in a substantially planar form. That is, to reduce step height issue and to obtain a fairly even upper final surface. More important, non-planarity problems are getting worse as the number of levels increase. Such step height issue complicates semiconductor manufacturing processes and adversely affects the performance and reliability of the semiconductor integrated circuit devices.

In view of the above, there exists a need for eliminating the step height issue in the semiconductor manufacturing processes.

### SUMMARY OF THE INVENTION

According to an aspect of the present invention, a conductive structure is provided. The conductive structure includes a wafer having a scribe line defined thereon, at least a first wiring layer formed in the scribe line, and at least a via layer formed in the scribe line and under the wiring layer. The first wiring layer includes a main pattern and the via layer includes a closed frame pattern corresponding to the main pattern of the first wiring layer.

According to another aspect of the present invention, an alignment mark structure is provided. The alignment mark structure includes a wafer having a scribe line defined thereon, at least a first wiring layer formed in the scribe line on the wafer, and a pair of via layers formed in the scribe line and under the first wiring layer. The via layers are respectively disposed at two opposite ends of the first wiring layer.

According to the conductive alignment mark structure provided by the present invention, the via layer is formed to have a closed frame pattern corresponding to the main pattern of the wiring layer. In other words, a pair of via layers are formed under the wiring layer, particularly at two opposite ends of the wiring layer when a cross-sectional view of the conductive alignment mark structure is taken. Accordingly, area occupied by the conductive material, specifically the via layer, is dramatically reduced and thus a planar and even surface is easily obtained. In other words, step height issue is eliminated and thus manufacturability of the semiconductor fabrication process and reliability of the semiconductor integrated circuit devices are both improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view of an alignment mark structure provided by a first preferred embodiment and a second preferred embodiment of the present invention.

FIGS. 2-3 are schematic drawings illustrating the alignment mark structure taken along a line A-A′ provided by the first preferred embodiment of the present invention, wherein FIG. 3 is a schematic drawing in a step subsequent to FIG. 2.

FIGS. 4-5 are schematic drawings illustrating the alignment mark structure taken along a line A-A′ provided by the second preferred embodiment of the present invention, wherein FIG. 5 is a schematic drawing in a step subsequent to FIG. 4.

### DETAILED DESCRIPTION

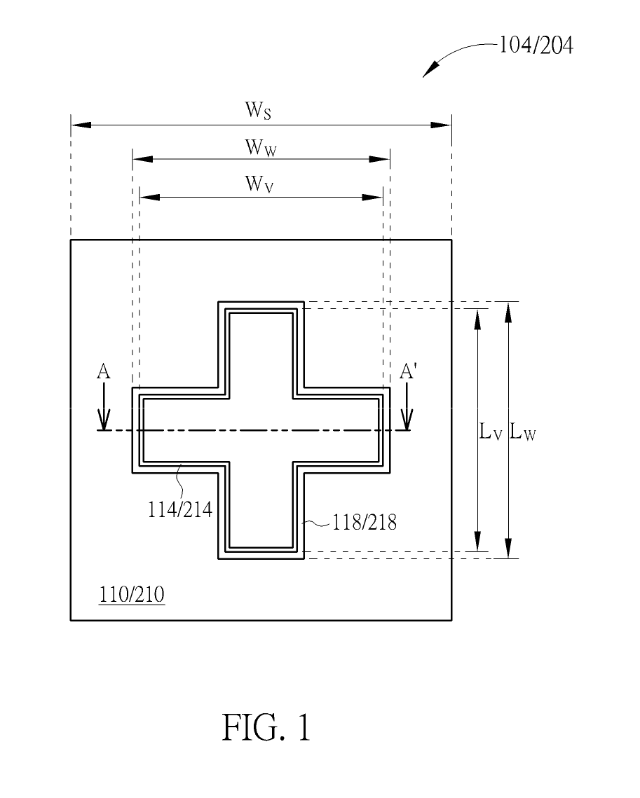

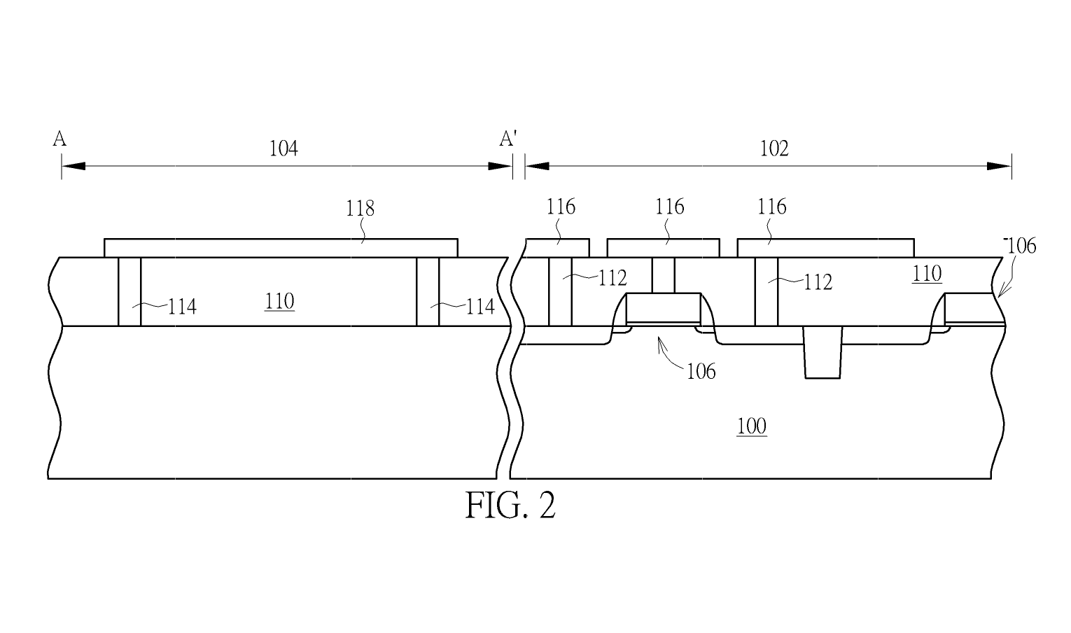

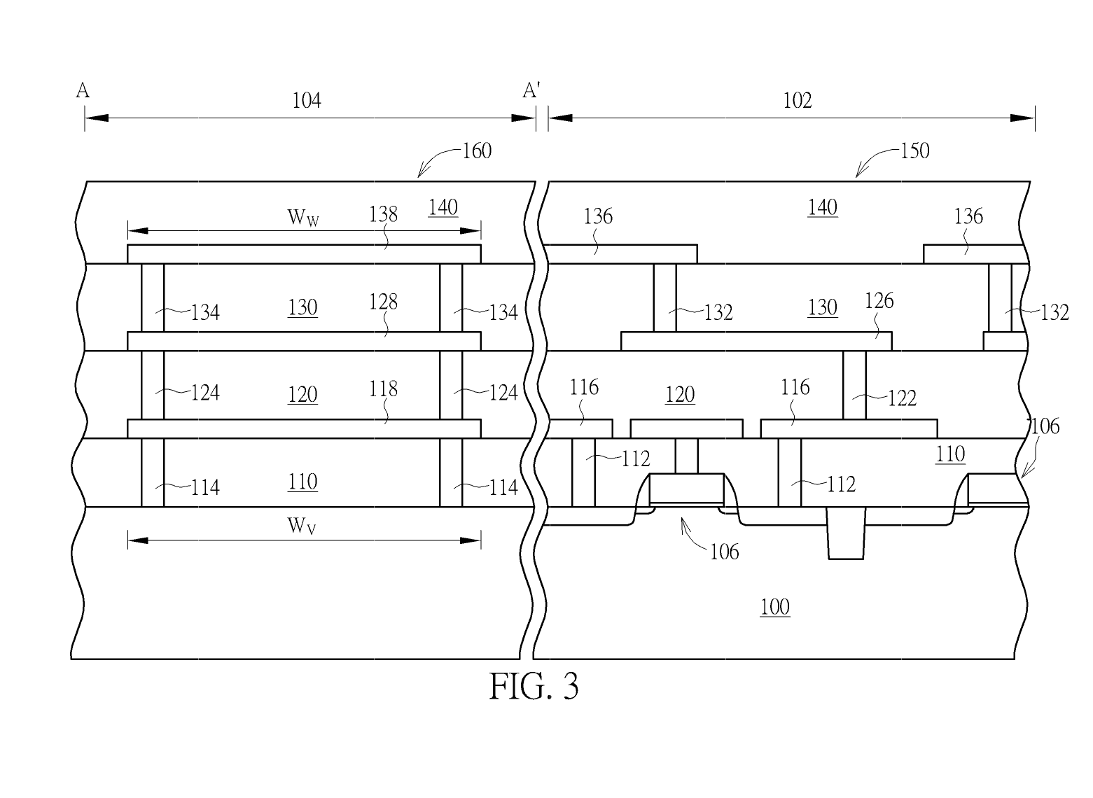

Please refer to FIGS. 1-3, wherein FIG. 1 is a top view of an alignment mark structure provided by a first preferred embodiment of the present invention, and FIGS. 2-3 are schematic drawings illustrating the alignment mark structure taken along a line A-A′ provided by the first preferred embodiment of the present invention. As shown in FIGS. 1-3, a wafer 100 including a silicon substrate is provided. A plurality of die regions 102 are defined by a scribe line 104. In accordance with the preferred embodiment, various devices, for example but not limited to metal-oxide-semiconductor (MOS) transistor device 106, for constructing integrated circuits are formed in die regions 102. As shown in FIGS. 1 and 2, an inter-layer dielectric layer (hereinafter abbreviated as ILD) layer 110 is then formed on the wafer 100.

Please refer to FIGS. 1-2. After forming the devices in the wafer 100, a multi-layered interconnection structure is to be fabricated. It is well-known to those skilled in the art the multi-layered interconnection structure is formed by many layers of the dielectric material accommodating conductive wirings patterns and via patterns, therefore accurate alignment between those patterns is essentially important, otherwise the electrical continuity of the multi-layered interconnection structure cannot be realized. Consequently, an alignment mark structure is to be formed in the scribe line 104. As shown in FIGS. 1 and 2, a plurality of via openings are formed in both of the die regions 102 and the scribe line 104. Subsequently, a conductive material is formed to fill up the via openings and followed by performing a planarization process. Thus, a plurality of contact plugs 112 are formed in the die region 102 and simultaneously a via layer 114 is formed in the scribe line 104. In other words, the contact plugs 112 and the via layer 114 are all embedded in the ILD layer 110. Furthermore, the conductive material includes tungsten (W) or aluminum (Al) in accordance with the preferred embodiment.

It is noteworthy that, an alignment mark structure is always provided with a predetermined shape, for example but not limited to a cross shape in accordance with the preferred embodiment as shown in FIG. 1. More important, the via layer 114 provided by the preferred embodiment includes a closed frame pattern corresponding to the predetermined shape of the alignment mark. More important, the via layer 114 and the contact plugs 112 are not only formed by the same fabrication steps, but also includes the same size. That is, a width of the via layer 114 complies with a minimum design rule for a contact plug/via in an interconnection structure.

Please still refer to FIGS. 1 and 2. Then, another conductive material (not shown) is formed on the ILD layer 110 and patterned. Consequently, wiring layers 116 are formed in the die region 102 and a wiring layer 118 is simultaneously formed in the scribe line 104. The conductive material includes W or Al in accordance with the preferred embodiment. As shown in FIG. 2, the wiring layers 116 and 118 are formed on the ILD layer 110. More important, the wiring layer 118 in the scribe line 104 is a part of the alignment mark structure and thus includes a main pattern with a particular shape, such as a cross shape in accordance with the preferred embodiment. It is observed that the via layer 114 is formed under the wiring layer 118, and the closed frame pattern of the via layer 114 corresponds to the main pattern of the wiring layer 118. More specific, the closed frame pattern of the via layer 114 extends along a contour of the main pattern of the wiring layer 118.

Please refer to FIG. 3. Thereafter, a dielectric layer 120 is formed on the wiring layers 116/118 and followed by forming via layers 122 and 124 embedded therein. As shown in FIG. 3, the via layers 122 are formed in the die region 102 while the via layer 124 is formed in the scribe line 104 correspondingly to the wiring layer 118. Next, another wiring layer 126 and 128 are formed on the dielectric layer 120. Such steps can be repeated any number of times. Consequently, a multi-layered interconnection structure 150 is formed in the die region 102 and a conductive alignment mark structure 160 is formed in the scribe line 104.

As shown in FIG. 3, the conductive alignment mark structure 160 includes wiring layers 118/128/138 and via layers 114/124/134 formed therebetween. The via layers 114/124/134 physically and electrically connected to the wiring layers 118/128/130. More important, the width of the via layers 114/124/134 of the conductive alignment mark structure 160 comply with the minimum design rule for the contact plug/via 112/122/132 in the multi-layered interconnection structure 150.

Please refer to FIGS. 1 and 3, again. According to the alignment mark structure 160 provided by the preferred embodiment, all of the wiring layers 118/128/138 include the main pattern and all of the via layers 114/124/134 include the closed frame pattern corresponding to the main pattern. It is also noteworthy that, as shown in FIGS. 1 and 3, because the alignment mark structure 160 is disposed in the scribe line 104, a width W_{W} and a length L_{w} of the main pattern of the wiring layer 118/128/138 is smaller than a width Ws of the scribe line 104. And a width Wᵥ and a length Lᵥ of the closed frame pattern of the via layer 114/124/134 is also is smaller than the width Ws of the scribe line 104. As mentioned above, the closed frame pattern of the via layers 114/124/134 extend along the contour of the main pattern of the wiring layers 118/128/138. Therefore, a pair of via layers 114/124/134 is always obtained at two opposite ends of the wiring layers 118/128/138 as shown in FIG. 3. Additionally, since the closed frame pattern of the via layers 114/124/134, which include the width comply with the minimum design rule, extend along the main pattern of the wiring layers 118/128/138, an area ratio between the via layers 114/124/134 over the wiring layers 114/124/134 is much smaller than 0.5.

It should be noted that in the prior art, the via layers of the conventional alignment mark often include the pattern the same with the wiring layer, and thus a large amount of the dielectric layer must be removed for accommodating the via pattern. That is, an area ratio between the via layers of the conventional alignment mark over the wiring layers of the conventional alignment mark is much larger than 0.5. However, since the via layer of the conventional alignment mark is simultaneously formed with the via in the interconnection structure, it is found that the via openings in the die region are filled up with metal while the larger opening in the scribe line suffers incompletely metal filling. And thus non-planar issue is generated. As mentioned afore, non-planarity problems are getting worse as the number of levels increase and irreparable step-height defect is finally caused. Different from the prior art, the via layers 114/124/134 of the conductive alignment mark structure 160 of the preferred embodiment include the width the same with the contact plug/via 112/122/132, and thus via openings for accommodating the contact plug/via/via layers are simultaneously filled up without forming any recess and even/planar surface of the dielectric layers 110/120/130/140 are easily obtained after planarization. In other words, step height issue is eliminated and thus manufacturability of the semiconductor fabrication process and reliability of the semiconductor integrated circuit devices are both improved.

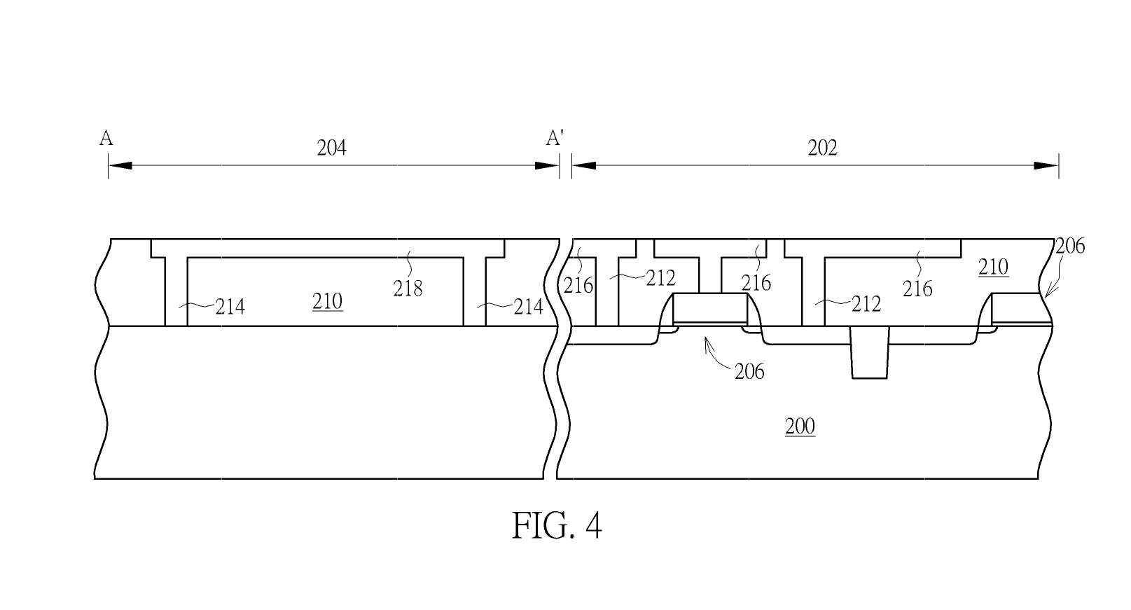

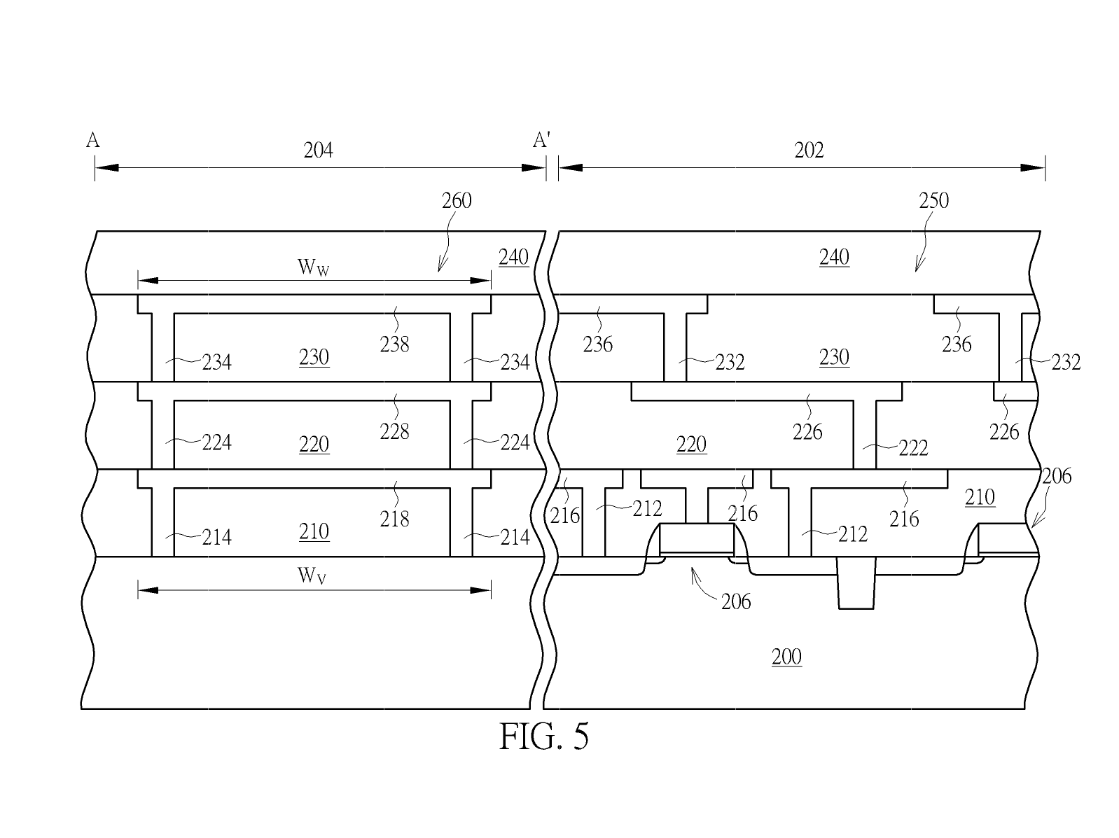

Please refer to FIGS. 1 and 4-5, wherein FIG. 1 is a top view of an alignment mark structure provided by a second preferred embodiment of the present invention, and FIGS. 4-5 are schematic drawings illustrating the alignment mark structure taken along a line A-A′ provided by the second preferred embodiment of the present invention. As shown in FIGS. 1 and 4-5, a wafer 200 including a silicon substrate is provided. A plurality of die regions 202 are defined by a scribe line 204 as shown in FIG. 4. In accordance with the preferred embodiment, various device, for example but not limited to MOS transistor device 206, for constructing integrated circuits are formed in die regions 202. As shown in FIGS. 1 and 4, an ILD layer 210 is then formed on the wafer 200.

Please refer to FIGS. 1 and 4 again. After forming the devices in the wafer 200, a multi-layered interconnection structure is to be fabricated. As mentioned above, accurate alignment between those patterns is essentially important in interconnection fabrication process, and thus an alignment mark structure is to be formed in the scribe line 204. It is noteworthy that the preferred embodiment adopts dual damascene approach. As shown in FIGS. 1 and 4, a plurality of via openings (not shown) and a plurality of wiring openings (not shown) are formed in both of the die regions 202 and the scribe line 204. Subsequently, a conductive material is formed to fill up the via openings and the wiring openings, and followed by performing a planarization process. Thus, a plurality of contact plugs 212 and a plurality of wiring layers 216 are formed in the die region 202, and simultaneously a via layer 214 and a wiring layer 218 are formed in the scribe line 204. In other words, the contact plugs 212, the via layer 214, and the wiring layers 216/218 are all embedded in the ILD layer 210. Furthermore, the conductive material includes copper (Cu) or Al in accordance with the preferred embodiment.

As mentioned above, an alignment mark structure is always provided with a predetermined shape, for example but not limited to a cross shape in accordance with the preferred embodiment as shown in FIG. 1. Therefore, the wiring layer 218 includes a main pattern having the cross shape and the via layer 214 formed under the wiring layer 218 includes a closed frame pattern corresponding to the main pattern of the wiring layer 218. More specific, the closed frame pattern of the via layer 214 extends along a contour of the main pattern of the wiring layer 218. More important, the via layer 214 and the contact plugs 212 are not only formed by the same fabrication step, but also includes the same size. That is, a width of the via layer 214 complies with a minimum design rule for a contact plug/via in an interconnection structure.

Please refer to FIG. 5. Thereafter, a dielectric layer 220 is formed on the dielectric layer 210 and followed by forming via openings (not shown) and wiring openings (not shown). The via openings and the wiring openings are then filled up with a conductive material and followed by planarization. Accordingly a plurality of vias 222 and a plurality of wiring layers 226 are embedded in the dielectric layer 220 in the die region 202. Simultaneously, a via layer 224 and a wiring layer 228 are embedded in the dielectric layer 220 in the scribe line 204. Such steps can be repeated any number of times. Consequently, a multi-layered interconnection structure 250 is formed in the die region 202 and a conductive alignment mark structure 260 is formed in the scribe line 204.

As shown in FIG. 5, the conductive alignment mark structure 260 includes wiring layers 218/228/238 and via layers 214/224/234 formed therebetween. The via layers 214/224/234 physically and electrically connected to the wiring layers 218/228/230. As mentioned above, a width of the via layers 214/224/234 of the conductive alignment mark structure 260 comply with a minimum design rule for a contact plug/via 212/222/232 in the interconnection structure 250.

Please refer to FIGS. 1 and 5, again. According to the alignment mark structure 260 provided by the preferred embodiment, All of the wiring layers 218/228/238 include the main pattern and all of the via layers 214/224/234 include the closed frame pattern corresponding to the main pattern. It is also noteworthy that, as shown in FIGS. 1 and 5, because the alignment mark structure 260 is disposed in the scribe line 204, a width W_{W} and a length L_{w} of the main pattern of the wiring layer 218/228/238 is smaller than a width Ws of the scribe line 104. And a width Wᵥ and a length Lᵥ of the closed frame pattern of the via layer 214/224/234 is also is smaller than the width Ws of the scribe line 204. As mentioned above, the closed frame pattern of the via layers 214/224/234 extend along the contour of the main pattern of the wiring layers 118/128/138. Therefore, a pair of via layers 214/224/234 is always obtained at two opposite ends of the wiring layers 218/228/238 as shown in FIG. 5. Additionally, since the closed frame pattern of the via layers 214/224/234, which include the width comply with the minimum design rule, extend along the main pattern of the wiring layers 218/228/238, an area ratio between the via layers 214/224/234 over the wiring layers 214/224/234 is much smaller than 0.5.

It should be noted that in the prior art, the via layers of the conventional alignment mark often include the pattern the same with the wiring layers, and thus a large amount of the dielectric layer must be removed for accommodating the via pattern. That is, an area ratio between the via layers of the conventional alignment mark over the wiring layers of the conventional alignment mark is much larger than 0.5. However, since the via layer and the wiring layer of the conventional alignment mark is simultaneously formed with the via and wiring layers in the interconnection structure, it is found that the via openings and the wiring openings in the die region are filled up with metal while the larger opening in the scribe line suffers incompletely metal filling. And thus non-planar issue is generated. As mentioned afore, non-planarity problems are getting worse as the number of levels increase and reparable step-height defect is finally caused. Different from the prior art, the via layers 214/224/234 of the conductive alignment mark structure 260 of the preferred embodiment include the width the same with the contact plug/via 212/222/232, and thus via openings for accommodating the contact plug/via/via layers are simultaneously filled up without forming any recess and even/planar surface of the dielectric layers 210/220/230/240 are easily obtained after planarization. In other words, step height issue is eliminated and thus manufacturability of the semiconductor fabrication process and reliability of the semiconductor integrated circuit devices are both improved.

According to the conductive alignment mark structure provided by the present invention, the via layer is formed as a closed frame pattern corresponding to the main pattern of the wiring layer. Therefore, a pair of via layers are formed under the wiring layer, particularly at two opposite ends of the wiring layer when a cross-sectional view of the conductive alignment mark structure is taken. Accordingly, area occupied by the conductive material, specifically the via layer, is dramatically reduced and thus a planar and even surface is easily obtained. In other words, step height issue is eliminated and thus manufacturability of the semiconductor fabrication process and reliability of the semiconductor integrated circuit devices are both improved. Additionally, the conductive alignment mark structure, which is electrically isolated from other devices or structures, can be formed in any interconnection fabrication process in state-of-the-art.

Those skilled in the art will readily observe that numerous modifications and alterations of the device and method may be made while retaining the teachings of the invention. Accordingly, the above disclosure should be construed as limited only by the metes and bounds of the appended claims.

1. A conductive structure comprising:
a wafer having a scribe line defined thereon;
at least a first wiring layer formed in the scribe line, the first wiring layer comprising a main pattern; and
at least a via layer formed in the scribe line and under the wiring layer, the via layer comprising a closed frame pattern corresponding to the main pattern of the first wiring layer.

2. The conductive structure according to claim 1, further comprising a dielectric layer, the via layer is embedded in the dielectric layer, and the first wiring layer is formed on the dielectric layer.

3. The conductive structure according to claim 2, wherein the first wiring layer and the via layer comprise tungsten (W) or aluminum (Al).

4. The conductive structure according to claim 1, further comprising a dielectric layer, and the first wiring layer and the via layer are embedded in the dielectric layer.

5. The conductive structure according to claim 4, wherein the first wiring layer and the via layer comprise copper (Cu) or Al.

6. The conductive structure according to claim 1, wherein the closed frame pattern of the via layer extends along a contour of the main pattern of the first wiring layer.

7. The conductive structure according to claim 1, further comprising a second wiring layer formed under the via layer, and the second wiring layer comprises the main pattern.

8. The conductive structure according to claim 1, wherein a width of the via layer complies with a minimum design rule for a via in an interconnection structure.

9. An alignment mark structure comprising:
a wafer having a scribe line defined thereon;
at least a first wiring layer formed in the scribe line on the wafer; and
a pair of via layers formed in the scribe line and under the first wiring layer, the via layers respectively disposed at opposite ends of the first wiring layer.

10. The alignment mark structure according to claim 9, further comprising a dielectric layer, the via layers are embedded in the dielectric layer, and the first wiring layer is formed on the dielectric layer.

11. The alignment mark structure according to claim 10, wherein the first wiring layer and the via layers comprise W or Al.

12. The alignment mark structure according to claim 9, further comprising a dielectric layer, and the first wiring layer and the via layers are embedded in the dielectric layer.

13. The alignment mark structure according to claim 12, wherein the first wiring layer and the via layers comprise Cu or Al.

14. The alignment mark structure according to claim 9, further comprising a second wiring layer formed under the via layer, and the second wiring layer comprises the main pattern.

15. The alignment mark structure according to claim 9, wherein a width of the via layer complies with a minimum design rule for a via in an interconnection structure.
